(19) United States
(12) Patent Application Publication
(10) Pub. No.: US 2025/0079202 A1
(43) Pub. Date: Mar. 6, 2025

(54) PHOTOHEATING APPARATUS AND FLOW PATH STRUCTURE

(71) Applicant: Ushio Denki Kabushiki Kaisha, Tokyo (JP)

(72) Inventor: Kazumasa YOSHIOKA, Tokyo (JP)

(73) Assignee: Ushio Denki Kabushiki Kaisha, Tokyo (JP)

(21) Appl. No.: 18/811,383

(22) Filed: Aug. 21, 2024

(30) Foreign Application Priority Data
Aug. 30, 2023 (JP) 2023-140041

(51) Int. Cl. H01L 21/67; F28F 9/22; H05B 3/00

(52) U.S. Cl. CPC H01L 21/67115; F28F 9/22; H05B 3/0047

(57) ABSTRACT

A photoheating apparatus includes: a light-emitting element substrate on which a plurality of light-emitting elements is mounted on a mounting surface being one main surface; a heat sink provided on a main surface of the light-emitting element substrate on a side opposite to the mounting surface, the heat sink including a plurality of heat absorbing flow paths through which a coolant flows; a flow path structure provided on a side surface of the heat sink opposite to the light-emitting element substrate, the flow path structure including a main body, a supply port through which the coolant flows from an outside to an inside of the main body, and a discharge port through which the coolant is discharged from the inside to the outside of the main body.

### CROSS-REFERENCE TO RELATED APPLICATION

The present invention claims the benefit of priority to Japanese Patent Application No. 2023-140041 filed on Aug. 30, 2023 with the Japanese Patent Office, the entire contents of which are incorporated herein by reference in its entirety.

### BACKGROUND OF THE INVENTION

### Field of the Invention

The present invention relates to a photoheating apparatus. The present invention also relates to a flow path structure mounted on the photoheating apparatus.

### Description of the Related Art

In a semiconductor manufacturing process, various types of heat treatment such as film forming treatment, oxidation diffusion treatment, reforming treatment, and annealing treatment are performed on an object to be processed such as a semiconductor wafer. Light is often used in performing these types of heat treatment. Heating the object to be processed by using the light in this manner is referred to as “photoheating”. In addition, the light used for heating is referred to as “heating light”.

As an apparatus for heating a semiconductor wafer by using the photoheating, a heating apparatus in which light-emitting diodes (LEDs), which are one of light-emitting elements, are mounted at high density is known. Here, it is known that the luminous efficiency of the light-emitting element such as an LED or a laser diode (LD) decreases when the temperature of the element itself increases. For this reason, for example, a heating apparatus including a cooling member to which a coolant is supplied is proposed in order to cool the LEDs mounted as a light-emitting element as described in Patent Document 1 below.

### PRIOR ART DOCUMENT

### Patent Document

Patent Document 1: JP-A-2010-153734

### SUMMARY OF THE INVENTION

A heating apparatus used in the process of manufacturing a semiconductor wafer is expected to be able to uniformly heat the entire semiconductor wafer as an object to be processed.

However, because a coolant flows in a predetermined flow path while absorbing heat from the light-emitting elements, the temperature of the coolant gradually increases. For this reason, as the overall length of the flow path through which the coolant flows while absorbing heat becomes longer, the amount of heat that can be absorbed by the coolant decreases toward the downstream. Such characteristics cause a difference in the luminous efficiency between the light-emitting element disposed on the upstream side of the flow path through which the coolant flows and the light-emitting element disposed on the downstream side, and cause uneven heating of the semiconductor wafer.

From the above circumstances, the present inventor has considered providing a plurality of flow paths through which the coolant flows to relatively shorten the flow path length of each of the flow paths. However, in a case where the plurality of flow paths are provided, a pipe for pouring the coolant and a pipe for guiding the coolant to be discharged need to be provided for each flow path.

In a case where the pipe for pouring the coolant and the pipe for guiding the coolant to be discharged are provided corresponding to each of the plurality of flow paths, a space for providing the pipe is required, which leads to an increase in size of the entire apparatus.

Note that, in order to split or merge the coolant, it is also conceivable to mount a manifold and combine the pipes in the middle. However, in a case where the manifold is mounted, an arrangement space of the manifold is required, and in addition, connection between the manifold and the cooling flow path becomes complicated, and an arrangement region is rather enlarged, and there is a possibility that the entire apparatus is enlarged.

In view of the above problems, it is an object of the present invention to provide a photoheating apparatus in which the entire mounted light-emitting elements can be cooled more homogeneously and the entire apparatus is downsized compared to the conventional apparatus.

A photoheating apparatus including:
a light-emitting element substrate on which a plurality of light-emitting elements is mounted on a mounting surface being one main surface;
a heat sink provided on a main surface of the light-emitting element substrate on a side opposite to the mounting surface, the heat sink including a plurality of heat absorbing flow paths through which a coolant flows;
a flow path structure provided on a side surface of the heat sink opposite to the light-emitting element substrate, the flow path structure including a main body, a supply port through which the coolant flows from an outside to an inside of the main body, and a discharge port through which the coolant is discharged from the inside to the outside of the main body,
in which the main body of the flow path structure includes:
a diverging part communicating with the supply port;
a merging part communicating with the discharge port;
a plurality of first flow paths that communicates the diverging part and each of the plurality of heat absorbing flow paths of the heat sink; and
a plurality of second flow paths that communicates the merging part and each of the plurality of heat absorbing flow paths at a portion different from a portion to which the first flow path of each of the plurality of heat absorbing flow paths of the heat sink is communicated.

In the photoheating apparatus having the above configuration, the coolant in a state where heat is hardly absorbed can be supplied to each of the plurality of heat absorbing flow paths, and the entire light-emitting element substrate can be uniformly cooled compared with the heat sink having only one heat absorbing flow path.

In addition, because the photoheating apparatus having the above-described configuration includes the flow path structure, it is not necessary to separately provide a pipe for pouring the coolant into each heat absorbing flow path of the heat sink, a pipe for discharging the coolant, and a manifold for causing the coolant to diverge or merge.

Note that, in the flow path structure, structures corresponding to the above pipes and manifolds are integrally formed inside the main body. Therefore, the flow path structure can be disposed in a narrower space than a case where pipes and manifolds are separately provided. That is, in the photoheating apparatus having the above configuration, the entire apparatus is downsized compared with the conventional apparatus.

In the photoheating apparatus described above,
the main body of the flow path structure may further include:
a first flow path plate including the diverging part and the plurality of first flow paths; and
a second flow path plate including the merging part and the plurality of second flow paths.

With the above configuration, the entire flow path structure is further downsized, and accordingly, the entire photoheating apparatus is downsized. Further, in a case where the first flow path plate and the second flow path plate can be separated, the plates can be replaced or cleaned individually.

Furthermore, in the photoheating apparatus described above,
in the main body of the flow path structure, the second flow path plate may be disposed closer to the heat sink than the first flow path plate.

In the first flow path included in the first flow path plate, a coolant having a relatively low temperature before heat is absorbed from the light-emitting element substrate flows. In the second flow path included in the second flow path plate, a coolant having a relatively high temperature after heat is absorbed from the light-emitting element substrate flows.

In a case where the first flow path plate is disposed closer to the heat sink than the second flow path plate, the coolant flowing through the first flow path absorbs heat from the heat sink and the second flow path plate, and the temperature rises before flowing into the heat sink. This causes a decrease in the amount of heat that can be absorbed from the light-emitting element substrate when the coolant flows through the heat absorbing flow path.

In the photoheating apparatus having the above configuration, the coolant flowing through the first flow path is prevented from absorbing heat from the heat sink. Therefore, the heat sink included in the photoheating apparatus having the above configuration can obtain a higher heat dissipation effect.

Furthermore, in the photoheating apparatus described above,
the main body of the flow path structure may have a heat insulating material disposed between the first flow path plate and the second flow path plate.

In the photoheating apparatus having the above configuration, the coolant flowing through the first flow path is prevented from absorbing heat from the second flow path plate. Therefore, the heat sink included in the photoheating apparatus having the above configuration can obtain a higher heat dissipation effect.

A flow path structure according to the present invention is a flow path structure included in the photoheating apparatus described above.

According to the present invention, a photoheating apparatus in which the entire mounted light-emitting elements can be cooled more homogeneously and the entire apparatus is downsized compared with the conventional apparatus is realized.

### BRIEF DESCRIPTION OF THE DRAWINGS

FIG. 1 is a cross-sectional view schematically illustrating a configuration of one embodiment of a photoheating apparatus;

FIG. 2 is a view of a heat sink as viewed from the +Z side;

FIG. 3 is a view of a first flow path plate as viewed from the +Z side;

FIG. 4 is a view of a second flow path plate as viewed from the +Z side; and

FIG. 5 is a view of a top plate as viewed from the +Z side.

### DETAILED DESCRIPTION OF THE PREFERRED EMBODIMENTS

Hereinafter, a photoheating apparatus and a flow path structure according to the present invention will be described with reference to the drawings. Note that all the following drawings are schematically illustrated, and the numbers of components on the drawings do not necessarily coincide with the actual numbers of components.

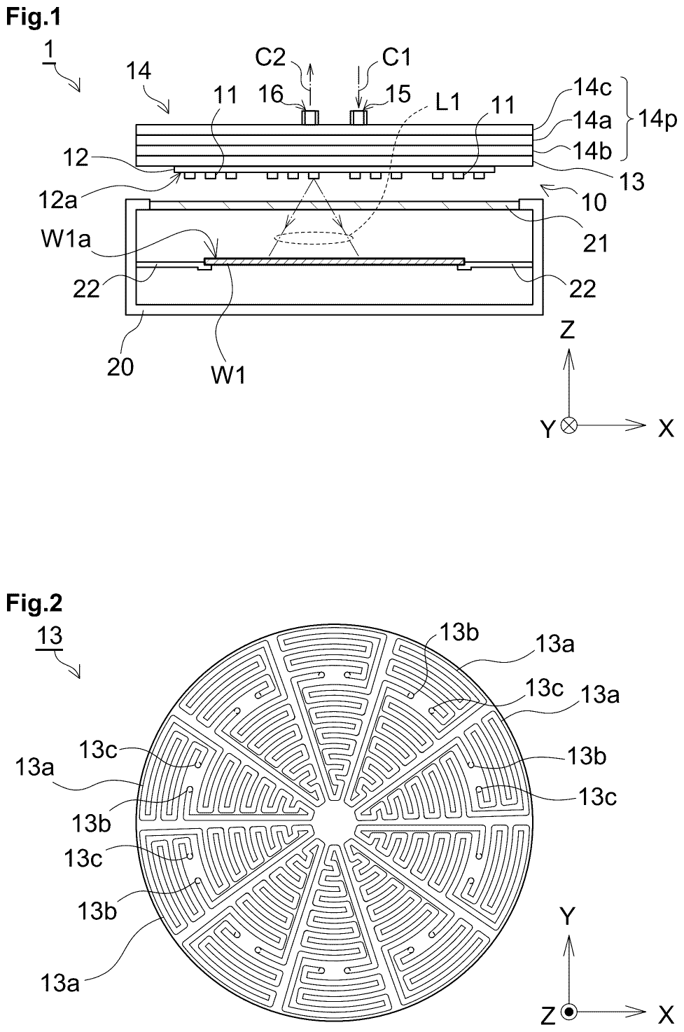

FIG. 1 is a cross-sectional view schematically illustrating a configuration of one embodiment of a photoheating apparatus 1. As illustrated in FIG. 1, the photoheating apparatus 1 includes a light source unit 10 and a chamber 20 in which a substrate to be processed W1 is accommodated. Note that the substrate to be processed W1 is assumed to be a semiconductor wafer, a display panel, a glass substrate, or the like. In addition, the semiconductor wafer is not particularly limited to a silicon (Si) substrate, and a silicon carbide (SiC) substrate or the like is also assumed.

In the following description, as illustrated in FIG. 1, a direction in which the light source unit 10 and the chamber 20 face each other is defined as the Z direction, and a plane orthogonal to the Z direction is defined as the XY plane. Note that, in the present embodiment, there is no circumstance to distinguish the X direction and the Y direction orthogonal to each other forming the XY plane, but for convenience of description, a direction in which a supply port 15 and a discharge port 16 described later are aligned will be described as the X direction.

Furthermore, positive and negative orientations distinguished from each other for directional expression will be described as the “+Z direction” and the “−Z direction” by adding positive and negative signs, while a direction expressed without distinction between the positive and negative orientations will be described simply as the “Z direction”.

As illustrated in FIG. 1, the light source unit 10 includes a plurality of light-emitting elements 11 that emit heating light L1, a light-emitting element substrate 12, a heat sink 13, and a flow path structure 14. The flow path structure 14 is provided with a supply port 15 for supplying a coolant C1 and a discharge port 16 for discharging a coolant C2, and is connected to a device (not illustrated) that controls supply and discharge of the coolant (C1, C2).

As illustrated in FIG. 1, the chamber 20 of the present embodiment includes a light-transmitting window 21 for taking in the heating light L1 emitted from the light source unit 10, and a support member 22 that supports the substrate to be processed W1 in the chamber. That is, the substrate to be processed W1 supported by the support member 22 is heat-treated by having a main surface Wla irradiated with the heating light L1 emitted from the light source unit 10 and taken in from the light-transmitting window 21.

The light-emitting element 11 in the present embodiment is an LED having a wavelength showing an intensity peak of a spectrum of emitted light of 395 nm. However, the light-emitting element 11 may be an LED showing the intensity peak in another wavelength band, or may be a light-emitting element other than the LED, for example, a laser diode (LD), a combination of an LED and an LD, or the like.

The light-emitting element substrate 12 is a substrate having the plurality of light-emitting elements 11 mounted on a mounting surface 12a which is one main surface, and a pattern and a wiring pattern for mounting the light-emitting elements 11 and circuit elements are formed on the mounting surface 12a.

In the present embodiment, only one light-emitting element substrate 12 is illustrated as illustrated in FIG. 1, but the light source unit 10 may include a plurality of the light-emitting element substrates 12. Note that, although it is merely an example, in consideration of the temperature distribution at the time of lighting, the light-emitting elements 11 are mounted such that the arrangement density on the mounting surface 12a of the light-emitting element substrate 12 is 2 pieces/cm² to 12 pieces/cm² and the total number of pieces in the light source unit 10 is about 1,500 to 8,500 pieces. In addition, the mounting density of the light-emitting elements 11 does not need to be uniform over the entire mounting surface 12a of the light-emitting element substrate 12, and the light-emitting element may be mounted within the above range of the mounting density in a predetermined arrangement region.

FIG. 2 is a view of the heat sink 13 as viewed from the +Z side. The heat sink 13 is provided on a main surface on a side opposite (+Z side) to the mounting surface 12a of the light-emitting element substrate 12. In the heat sink 13 according to the present embodiment, a plurality of heat absorbing flow paths 13a for allowing the coolant C1 to flow are formed on the main surface on the +Z side. The shape of the heat absorbing flow path 13a is appropriately adjusted according to the temperature distribution during the operation of the light-emitting element substrate 12, and the shape of the heat absorbing flow path 13a illustrated in FIG. 2 is merely an example.

The heat sink 13 according to the present embodiment is a plate made of copper, but as the material of the heat sink 13, for example, aluminum, stainless steel, or the like can be adopted in addition to copper.

The heat absorbing flow path 13a is a recess formed on the main surface on the +Z side of the heat sink 13, and as illustrated in FIG. 1, by having the flow path structure 14 (a second flow path plate 14b) disposed on the +Z side to close the recess, a closed flow path through which the coolant C1 can flow is formed. Note that the heat absorbing flow path 13a may be formed inside the heat sink 13 so that the coolant C1 can flow without requiring the flow path structure 14.

The coolant C1 is poured from the flow path structure 14 to a one end part 13b of the heat absorbing flow path 13a, flows through the heat absorbing flow path 13a while absorbing the heat generated by the light-emitting elements 11, and is discharged from an other end part 13c to the flow path structure 14 as the coolant C2 in a state of having the heat absorbed. Note that the flow direction of the coolant C1 may be reversed, and a configuration may be changed to the one in which the coolant C1 flows to the other end part 13c and is discharged from the one end part 13b to the flow path structure 14 as the coolant C2.

Here, the coolant C1 and the coolant C2 are selectively used to distinguish whether it is the coolant flowing until simply reaching the other end part 13c of the heat absorbing flow path 13a or the coolant after being discharged from the other end part 13c of the heat absorbing flow path 13a.

Note that, although the coolant (C1, C2) in the present embodiment is water, a coolant other than water may be adopted.

As illustrated in FIG. 1, the flow path structure 14 includes: a main body 14p formed by stacking a first flow path plate 14a, the second flow path plate 14b, and a top plate 14c; the supply port 15 through which the coolant C1 is supplied; and the discharge port 16 through which the coolant C2 is discharged.

In the main body 14p in the present embodiment, the second flow path plate 14b, the first flow path plate 14a, and the top plate 14c are stacked in this order from the surface of the light-emitting element substrate 12 opposite to the mounting surface 12a toward the +Z side so as not to absorb heat as much as possible before the coolant C1 reaches the heat sink 13. However, in a case where the heat exchange between the flow path plates does not cause a large problem, the order of stacking the first flow path plate 14a, the second flow path plate 14b, and the top plate 14c may not be the above order.

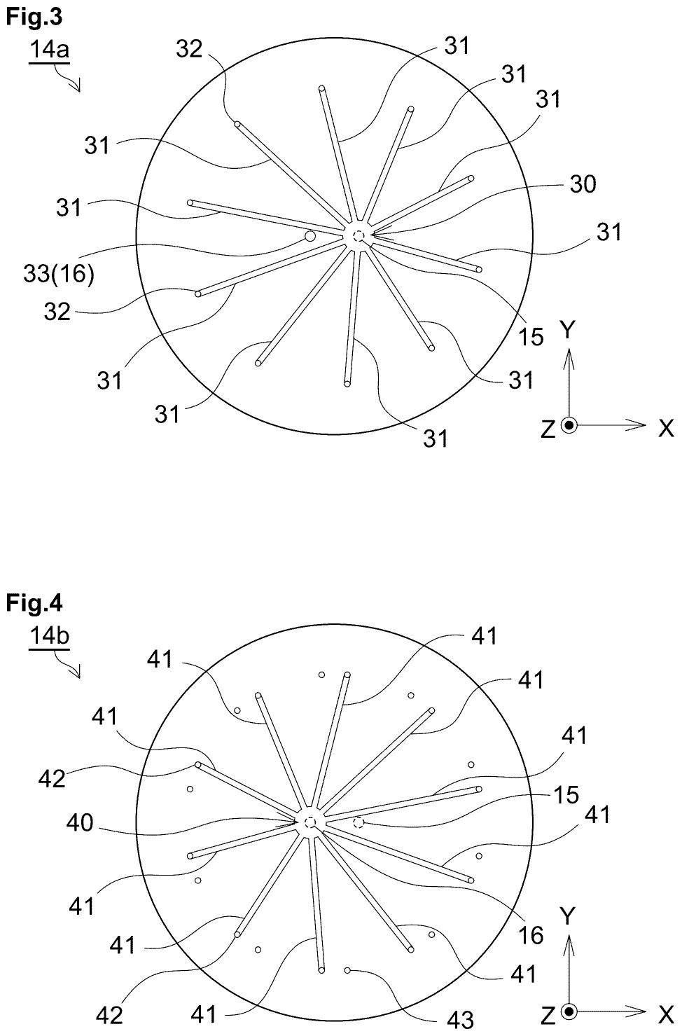

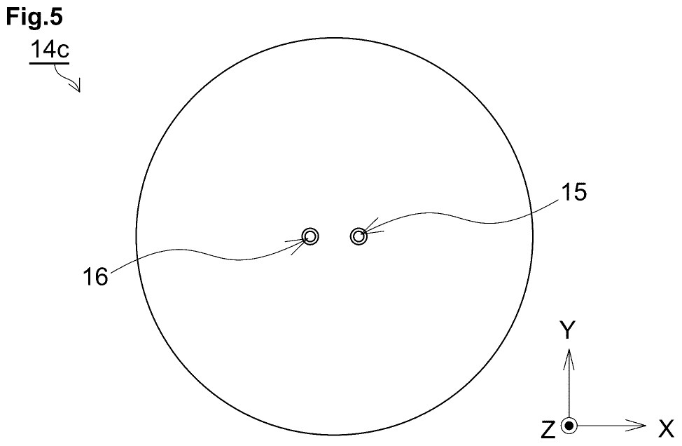

FIG. 3 is a view of the first flow path plate 14a as viewed from the +Z side, FIG. 4 is a view of the second flow path plate 14b as viewed from the +Z side, and FIG. 5 is a view of the top plate 14c as viewed from the +Z side. In FIGS. 3 and 4, the supply port 15 and the discharge port 16 are virtually illustrated by broken lines at the positions of the supply port 15 and the discharge port 16 as viewed in the Z direction. However, in FIG. 3, the broken line indicating the discharge port 16 and a through hole 33 to be described later overlap each other in the same shape.

Furthermore, in FIGS. 1 to 5, a specific structure for stacking and fixing the heat sink 13 and each of the plates (14a, 14b, 14c) is omitted for convenience of illustration. These members may be fixed by any method such as fixing by a bolt and a nut, fixing by a clamping member, fixing by a fitting part formed on each member, and joining by brazing using a brazing material.

As illustrated in FIG. 3, the first flow path plate 14a is formed with, on the main surface on the +Z side, a diverging part 30, a plurality of through holes 32 each connected to the one end part 13b of the heat absorbing flow path 13a of the heat sink 13 in a state of being combined with the heat sink 13, and a plurality of first flow paths 31 each communicated to the diverging part 30 and the corresponding one of the plurality of through holes 32. Note that the first flow path 31 only needs to be able to sequentially supply the coolant C1 to the heat sink 13, and may not necessarily be connected to the one end part 13b of the heat absorbing flow path 13a.

Note that the shapes of the diverging part 30 and the first flow path 31 are appropriately adjusted according to the shape of the heat absorbing flow path 13a of the heat sink 13, and the shape of the first flow path 31 illustrated in FIG. 3 is merely an example.

In addition, the first flow path plate 14a is provided with the through hole 33 for guiding the coolant C2 discharged from the second flow path plate 14b to the discharge port 16 of the top plate 14c.

The first flow path plate 14a according to the present embodiment is a plate made of copper, but as the material of the first flow path plate 14a, aluminum, stainless steel, or the like can be adopted in addition to copper.

The diverging part 30 and the first flow paths 31 are recesses formed on the main surface on the +Z side of the first flow path plate 14a, and as illustrated in FIG. 1, by having the top plate 14c disposed on the +Z side to close the recesses, a closed flow path through which the coolant C1 can flow is formed.

Note that the diverging part 30 and the first flow paths 31 may be formed by excavating the inside of the first flow path plate 14a so that the coolant C1 can flow without requiring the top plate 14c.

As illustrated in FIG. 4, the second flow path plate 14b is formed with, on the main surface on the +Z side, a merging part 40, a plurality of through holes 42 each connected to the other end part 13c of the heat absorbing flow path 13a of the heat sink 13 in a state of being combined with the heat sink 13, and a plurality of second flow paths 41 each communicated to the merging part 40 and the corresponding one of the plurality of through holes 42. Note that the second flow path 41 only needs to be able to sequentially discharge the coolant C2 from the heat sink 13, and may not necessarily be connected to the other end part 13c of the heat absorbing flow path 13a.

Note that the shapes of the merging part 40 and the second flow path 41 are appropriately adjusted according to the shape of the heat absorbing flow path 13a of the heat sink 13, and the shape of the second flow path 41 illustrated in FIG. 4 is merely an example.

In addition, the second flow path plate 14b is provided with a through hole 43 for guiding the coolant C1 discharged from the first flow path plate 14a to the one end part 13b of the heat absorbing flow path 13a of the heat sink 13.

The second flow path plate 14b according to the present embodiment is a plate made of copper, but as the material of the second flow path plate 14b, aluminum, stainless steel, or the like can be adopted in addition to copper.

The merging part 40 and the second flow paths 41 are recesses formed on the main surface on the +Z side of the second flow path plate 14b, and as illustrated in FIG. 1, by having the first flow path plate 14a disposed on the +Z side to close the recesses, a closed flow path through which the coolant C2 can flow is formed.

Note that the merging part 40 and the second flow paths 41 may be formed by excavating the inside of the second flow path plate 14b so that the coolant C2 can flow without requiring the first flow path plate 14a.

As illustrated in FIG. 5, the top plate 14c is a member in which the supply port 15 and the discharge port 16 are formed on the main surface on the +Z side. As described above, the top plate 14c in the present embodiment has a function as a lid for forming the flow path of the first flow paths 31 of the first flow path plate 14a.

Note that, for example, in a case where the first flow paths 31 are formed inside the first flow path plate 14a and the top plate 14c is unnecessary, the supply port 15 and the discharge port 16 may be formed directly on the first flow path plate 14a or the second flow path plate 14b without having the top plate 14c provided.

The top plate 14c according to the present embodiment is a plate made of copper, but as the material of the top plate 14c, aluminum, stainless steel, or the like can be adopted in addition to copper. Note that, although preferable materials have been exemplified for each of the plates (14a, 14b, 14c), it is preferable that all the materials of the plates (14a, 14b, 14c) are made of the same material in consideration of easiness of joining by brazing and occurrence of electrolytic corrosion. Furthermore, also in consideration of thermal conductivity, each of the plates (14a, 14b, 14c) is preferably a plate made of copper.

Here, the thickness of each of the plates (14a, 14b, 14c) is optional, but from the viewpoint of not enlarging the entire apparatus, all of the plates (14a, 14b, 14c) are preferably in a range of 1 mm to 50 mm, and more preferably in a range of 2 mm to 30 mm. Note that the thickness of each of the plates (14a, 14b, 14c) may be different from each other.

Furthermore, the main body 14p may not be separable into a plurality of plates, and may be configured as a member having an integrated configuration in which all the functions of the plates (14a, 14b, 14c) are provided. For example, the main body 14p may be a member in a form of a block-shaped object that has been subjected to cutting work to have the diverging part 30, the plurality of first flow paths 31, the merging part 40, and the plurality of second flow paths 41 formed inside, or may be a member having an integrated configuration in which all the plates (14a, 14b, 14c) are bonded or welded.

With the above configuration, the coolant C1 in a state where heat is hardly absorbed can be supplied to each of the plurality of heat absorbing flow paths 13a of the heat sink 13, and the entire light-emitting element substrate 12 can be uniformly cooled compared with the conventional heat sink having only one heat absorbing flow path.

In addition, in the photoheating apparatus 1 having the above-described configuration, by including the flow path structure 14, it is not necessary to separately provide a pipe for pouring the coolant C1 into each of the heat absorbing flow paths 13a of the heat sink 13, a pipe for discharging the coolant C2, and a manifold for causing the coolant (C1, C2) to diverge or merge. That is, the entire photoheating apparatus 1 is downsized compared with the conventional photoheating apparatus.

### OTHER EMBODIMENTS

Other embodiments will be described below.

<1> In the above-described embodiment, the main body 14p included in the flow path structure 14 is configured such that the first flow path plate 14a and the second flow path plate 14b are in direct contact with each other. However, in the flow path structure 14, a heat insulating material may be disposed between the first flow path plate 14a and the second flow path plate 14b.

The heat insulating material is, for example, a ceramic plate or the like. In a case where the heat insulating material is sandwiched between the first flow path plate 14a and the second flow path plate 14b, holes for allowing the coolant (C1, C2) to flow are formed at positions corresponding to the through holes (32, 33, 42, 43) respectively formed in the corresponding one of the plates (14a, 14b) so as not to obstruct the flow of the coolant (C1, C2).

Note that the heat insulating material does not need to have the same shape as the first flow path plate 14a or the second flow path plate 14b when viewed in the Z direction, and may have any shape.

<2> The configurations of the photoheating apparatus 1 and the flow path structure 14 described above are merely examples, and the present invention is not limited to each of the illustrated configurations.

What is claimed is:

1. A photoheating apparatus comprising:
a light-emitting element substrate on which a plurality of light-emitting elements is mounted on a mounting surface being one main surface;
a heat sink provided on a main surface of the light-emitting element substrate on a side opposite to the mounting surface, the heat sink including a plurality of heat absorbing flow paths through which a coolant flows;
a flow path structure provided on a side surface of the heat sink opposite to the light-emitting element substrate, the flow path structure including a main body, a supply port through which the coolant flows from an outside to an inside of the main body, and a discharge port through which the coolant is discharged from the inside to the outside of the main body, wherein the main body of the flow path structure includes:
a diverging part communicating with the supply port;
a merging part communicating with the discharge port;
a plurality of first flow paths that communicates the diverging part and each of the plurality of heat absorbing flow paths of the heat sink; and
a plurality of second flow paths that communicates the merging part and each of the plurality of heat absorbing flow paths at a portion different from a portion to which the first flow path of each of the plurality of heat absorbing flow paths of the heat sink is communicated.

2. The photoheating apparatus according to claim 1, wherein the main body of the flow path structure further includes:
a first flow path plate including the diverging part and the plurality of first flow paths; and
a second flow path plate including the merging part and the plurality of second flow paths.

3. The photoheating apparatus according to claim 2, wherein, in the main body of the flow path structure, the second flow path plate is disposed closer to the heat sink than the first flow path plate.

4. The photoheating apparatus according to claim 2, wherein the main body of the flow path structure has a heat insulating material disposed between the first flow path plate and the second flow path plate.

5. A flow path structure provided in the photoheating apparatus according to claim 1.

6. A flow path structure provided in the photoheating apparatus according to claim 2.

7. A flow path structure provided in the photoheating apparatus according to claim 3.

8. A flow path structure provided in the photoheating apparatus according to claim 4.
